(19) United States
(12) Patent Application Publication
(10) Pub. No.: US 2024/0136389 A1
(43) Pub. Date: Apr. 25, 2024

(54) LIGHT EMITTING DEVICE

(71) Applicant: TOYODA GOSEI CO., LTD., Kiyosu-shi (JP)

(72) Inventor: Koichi GOSHONOO, Kiyosu-shi (JP)

(21) Appl. No.: 18/380,923

(22) Filed: Oct. 16, 2023

(30) Foreign Application Priority Data
Oct. 18, 2022 (JP) 2022-167819

(51) Int. Cl. H01L 27/15

(52) U.S. Cl. CPC H01L 27/156; H01L 25/18

(57) ABSTRACT

A light emitting device includes a plurality of light emitting units located side by side on a single substrate and each emitting light independently. Each of the plurality of light emitting units includes an n-type semiconductor layer, a light emitting layer, a p-type semiconductor layer, a p-side contact electrode, and a p-side junction electrode. The n-type semiconductor layer and the p-type semiconductor layer of the plurality of light emitting units are respectively provided in an n-type semiconductor film and a p-type semiconductor film, which are single continuous films commonly used for the plurality of light emitting units. An n-side junction electrode is commonly connected to the n-type semiconductor layers of the plurality of light emitting units. The width of the p-side contact electrode is smaller than the width of the p-side junction electrode.

### CROSS-REFERENCE TO RELATED APPLICATION

This application is based on and claims priority under 35 USC 119 from Japanese Patent Application No. 2022-167819 filed on Oct. 19, 2022.

### TECHNICAL FIELD

The present disclosure relates to a light emitting device.

### BACKGROUND ART

In the related art, a light emitting device including a plurality of light emitting units which are located side by side on a single substrate and each emits light independently has been known (see JP2021-158179A). In the light emitting device described in JP2021-158179A, a stacked semiconductor film is commonly used for the plurality of light emitting units, and the stacked semiconductor film includes layers which constitute each light emitting unit, such as light emitting layers. Therefore, the pitch of the light emitting units can be narrowed compared to the case where the light emitting units are provided separately.

However, in the light emitting device described in JP2021-158179A, since the stacked semiconductor film is commonly used for the plurality of light emitting units, when the pitch of the light emitting units is small, the current for causing a particular light emitting unit to emit light may flow into the adjacent light emitting unit and cause the light emitting layer thereof to emit light.

In a case where the light emitting layers of adjacent light emitting units are caused to emit light by the current for causing the particular light emitting unit to emit light, when the adjacent light emitting units emit light in different colors, the color purity and contrast of the light emitted from the plurality of light emitting units may deteriorate. Moreover, even when the adjacent light emitting units emit light in the same color, the contrast of the light emitted from the plurality of light emitting units may deteriorate.

### SUMMARY OF INVENTION

An object of the present disclosure is to provide a light emitting device in which a semiconductor film is commonly used for a plurality of light emitting units, and in which the current for causing a particular light emitting unit to emit light is prevented from causing the light emitting layers of the adjacent light emitting units to emit light.

One embodiment of the present disclosure provides a light emitting devices of (1) to (5) below in order to achieve the above object.

(1) A light emitting device including a plurality of light emitting units located side by side on a single substrate and each emitting light independently, in which each of the plurality of light emitting units includes: an n-type semiconductor layer; a light emitting layer above the n-type semiconductor layer; a p-type semiconductor layer above the light emitting layer; a p-side contact electrode connected to an upper surface of the p-type semiconductor layer; and a p-side junction electrode connected to an upper surface of the p-side contact electrode, the n-type semiconductor layer and the p-type semiconductor layer of the plurality of light emitting units are respectively provided in an n-type semiconductor film and a p-type semiconductor film, which are single continuous films commonly used for the plurality of light emitting units, an n-side junction electrode is commonly connected to the n-type semiconductor layers of the plurality of light emitting units, and the width of the p-side contact electrode is smaller than the width of the p-side junction electrode.

(2) The light emitting device according to (1) described above, in which the p-side junction electrode does not cover a side surface of the p-side contact electrode.

(3) The light emitting device according to (1) described above, in which the p-side junction electrode covers a side surface of the p-side contact electrode.

(4) The light emitting device according to any one of (1) to (3) described above, in which in the plurality of light emitting units, adjacent light emitting units emit light in different colors.

(5) The light emitting device according to any one of (1) to (3) described above, in which the n-side junction electrode is located outside the plurality of light emitting units.

According to the present disclosure, it is possible to provide a light emitting device in which a semiconductor film is commonly used for a plurality of light emitting units, and in which the current for causing a particular light emitting unit to emit light is prevented from causing the light emitting layers of the adjacent light emitting units to emit light.

### BRIEF DESCRIPTION OF DRAWINGS

FIG. 1 is a vertical cross-sectional view of a light emitting device according to a first embodiment of the present disclosure.

FIGS. 2A to 2D are vertical cross-sectional views illustrating manufacturing steps of the light emitting device according to the first embodiment of the present disclosure.

FIGS. 3A to 3C are vertical cross-sectional views illustrating manufacturing steps of the light emitting device according to the first embodiment of the present disclosure.

FIG. 4 is a vertical cross-sectional view of a modification of the light emitting device according to the first embodiment of the present disclosure.

FIG. 5 is a vertical cross-sectional view of a mounting example of the light emitting device according to the first embodiment of the present disclosure.

FIG. 6 is a vertical cross-sectional view of a light emitting device according to a second embodiment of the present disclosure.

### DESCRIPTION OF EMBODIMENTS

### First Embodiment

(Configuration of Light Emitting Device)

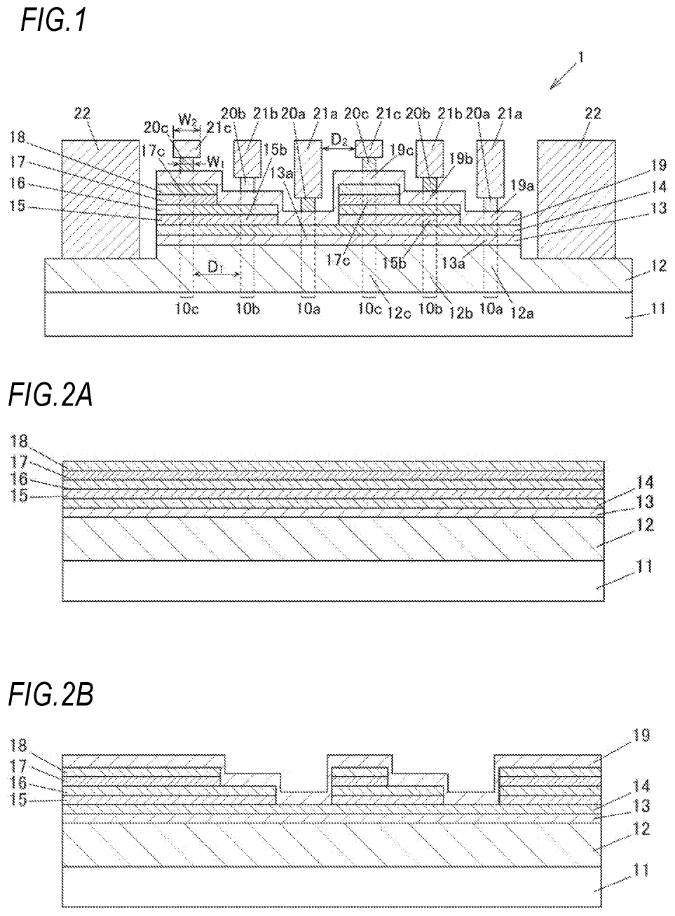

FIG. 1 is a vertical cross-sectional view of a light emitting device 1 according to a first embodiment of the present disclosure. The light emitting device 1 includes a substrate 11 such as a sapphire substrate, and a plurality of light emitting units 10 (10a to 10c) located side by side on the substrate 11 and independently emitting light in different colors. The number of light emitting units 10 provided in the light emitting device 1 is not particularly limited. Further, in the example illustrated in FIG. 1, the light emitting device 1 can emit light of three colors from the light emitting units 10a to 10c, but the number of light emitting colors in the light emitting device 1 is not limited to this.

The light emitting device 1 is a light emitting device of a type having a plurality of light emitting units on a single substrate, which is called a monolithic type, and can be used alone as a single small display (with a width of several mm to 10 mm, for example). In this case, for example, an image displayed by the light emitting device 1 can be enlarged and projected like a projector.

The light emitting device 1 includes an n-type semiconductor film 12 provided in a region including the light emitting units 10a to 10c, a first semiconductor film 13 provided on the n-type semiconductor film 12 in a region including the light emitting units 10a to 10c, a first intermediate film 14 provided on the first semiconductor film 13 in a region including the light emitting units 10a to 10c, a second semiconductor film 15 provided on the first intermediate film 14 in a region including the light emitting units 10b and 10c, a second intermediate film 16 provided on the second semiconductor film 15 in a region including the light emitting units 10b and 10c, a third semiconductor film 17 provided on the second intermediate film 16 in a region including the light emitting unit 10c, a third intermediate film 18 provided on the third semiconductor film 17 in a region including the light emitting unit 10c, and a p-type semiconductor film 19 covering a top of the first intermediate film 14, a top of the second intermediate film 16, and a top of the third intermediate film 18 in a region including the light emitting unit 10a, a region including the light emitting unit 10b, and a region including the light emitting unit 10c, respectively.

The n-type semiconductor film 12, the first semiconductor film 13, and the first intermediate film 14 are each a single continuous film commonly used for the light emitting units 10a to 10c. The n-type semiconductor film 12 is used as an n-type semiconductor layer of the light emitting units 10a to 10c. The first semiconductor film 13 is used as a light emitting layer 13a of the light emitting unit 10a. The first intermediate film 14 is used as a cap layer of the light emitting unit 10a.

The second semiconductor film 15 and the second intermediate film 16 are each a single continuous film commonly used for the adjacent light emitting units 10b and 10c. In the example illustrated in FIG. 1, the light emitting device 1 includes two second semiconductor films 15 and two second intermediate films 16. The second semiconductor film 15 is used as a light emitting layer 15b of the light emitting unit 10b. The second intermediate film 16 is used as a cap layer of the light emitting unit 10b.

The third semiconductor film 17 and the third intermediate film 18 are each used for the light emitting unit 10c. In the example illustrated in FIG. 1, the light emitting device 1 includes two third semiconductor films 17 and two third intermediate films 18. The third semiconductor film 17 is used as a light emitting layer 17c of the light emitting unit 10c. The third intermediate film 18 is used as a cap layer of the light emitting unit 10c.

The p-type semiconductor film 19 is a single continuous film commonly used for the light emitting units 10a to 10c. The p-type semiconductor film 19 is used as the p-type semiconductor layers 19a to 19c of the light emitting units 10a to 10c.

The light emitting unit 10a includes an n-type semiconductor layer 12a which is part of the n-type semiconductor film 12, a light emitting layer 13a which is part of the first semiconductor film 13 on the n-type semiconductor 12a, a p-type semiconductor layer 19a which is a part of the p-type semiconductor film 19 above the light emitting layer 13a, a p-side contact electrode 20a connected to the upper surface of the p-type semiconductor layer 19a, and a p-side junction electrode 21a connected to the upper surface of the p-side contact electrode 20a. The first intermediate film 14 is provided between the light emitting layer 13a and the p-type semiconductor layer 19a.

The light emitting unit 10b includes an n-type semiconductor layer 12b which is part of the n-type semiconductor film 12, a light emitting layer 15b which is part of the second semiconductor film 15 above the n-type semiconductor layer 12b, a p-type semiconductor layer 19b which is a part of the p-type semiconductor film 19 above the light emitting layer 15b, a p-side contact electrode 20b connected to the upper surface of the p-type semiconductor layer 19b, and a p-side junction electrode 21b connected to the upper surface of the p-side contact electrode 20b. The first semiconductor film 13 and the first intermediate film 14 are provided between the n-type semiconductor layer 12b and the light emitting layer 15b. The second intermediate film 16, the third semiconductor film 17, and the third intermediate film 18 are provided between the light emitting layer 15b and the p-type semiconductor layer 19b.

The light emitting unit 10c includes an n-type semiconductor layer 12c which is part of the n-type semiconductor film 12, a light emitting layer 17c which is part of the third semiconductor film 17 above the n-type semiconductor layer 12c, a p-type semiconductor layer 19c which is part of the p-type semiconductor film 19 above the light emitting layer 17c, a p-side contact electrode 20c connected to the upper surface of the p-type semiconductor layer 19c, and a p-side junction electrode 21c connected to the upper surface of the p-side contact electrode 20c. The first semiconductor film 13, the first intermediate film 14, the second semiconductor film 15, and the second intermediate film 16 are provided between the n-type semiconductor layer 12c and the light emitting layer 17c. The third intermediate film 18 is provided between the light emitting layer 17c and the p-type semiconductor layer 19c.

An n-side junction electrode 22 is connected on the n-type semiconductor film 12 commonly used for the light emitting units 10a to 10c. That is, the n-side junction electrode 22 is commonly connected to the n-type semiconductor layers 12a to 12c of the light emitting units 10a to 10c. In the light emitting device 1, since the plurality of light emitting units 10a to 10c normally constitute one display region, the n-side junction electrode 22 is preferably located outside the plurality of light emitting units 10a to 10c.

A bandgap of the first intermediate film 14 is larger than bandgaps of the first semiconductor film 13, the second semiconductor film 15, and the third semiconductor film 17. A bandgap of the second intermediate film 16 is larger than bandgaps of the second semiconductor film 15 and the third semiconductor film 17. Also, a bandgap of the third intermediate film 18 is larger than the bandgap of the third semiconductor film 17.

The first semiconductor film 13, the second semiconductor film 15, and the third semiconductor film 17 may have a multi quantum well (MQW) structure. In that case, bandgaps of wells forming the multi quantum well are the bandgaps of the first semiconductor film 13, the second semiconductor film 15, and the third semiconductor film 17.

Since the multi quantum well structure is generally more efficient than the single quantum well structure, it is preferable that the first semiconductor film 13, the second semiconductor film 15, and the third semiconductor film 17 have multi quantum well structures. On the other hand, since the single quantum well structure has a higher response speed (time from voltage application to light emission), either the multi quantum well structure or the single quantum well structure can be used depending on the use.

The bandgap of the second semiconductor film 15 is smaller than the bandgap of the first semiconductor film 13, and the bandgap of the third semiconductor film 17 is smaller than the bandgap of the second semiconductor film 15.

In the light emitting unit 10a, the light emitting layer 13a emits light when a voltage is applied between the n-side junction electrode 22 and p-side junction electrode 21a so that a side of the p-type semiconductor film 19 becomes the anode and a side of the n-type semiconductor film 12 becomes the cathode. In the light emitting unit 10a, since the current injected from the p-side contact electrode 20a into the stacked body from the n-type semiconductor film 12 to the p-type semiconductor film 19 mainly flows downward (in the thickness direction of the stacked body), portions of the n-type semiconductor film 12, the first semiconductor film 13, and the p-type semiconductor film 19 located immediately below the p-side contact electrode 20a mainly function as the n-type semiconductor layer 12a, the light emitting layer 13a, and the p-type semiconductor layer 19a, respectively.

In the light emitting unit 10b, the light emitting layer 15b emits light when a voltage is applied between the n-side junction electrode 22 and p-side junction electrode 21b so that the side of the p-type semiconductor film 19 becomes the anode and the side of the n-type semiconductor film 12 becomes the cathode. In the light emitting unit 10b, since the current injected from the p-side contact electrode 20b into the stacked body from the n-type semiconductor film 12 to the p-type semiconductor film 19 mainly flows downward (in the thickness direction of the stacked body), portions of the n-type semiconductor film 12, the second semiconductor film 15, and the p-type semiconductor film 19 located immediately below the p-side contact electrode 20b mainly function as the n-type semiconductor layer 12b, the light emitting layer 15b, and the p-type semiconductor layer 19b, respectively.

In the light emitting unit 10c, the light emitting layer 17c emits light when a voltage is applied between the n-side junction electrode 22 and p-side junction electrode 21c so that the side of the p-type semiconductor film 19 becomes the anode and the side of the n-type semiconductor film 12 becomes the cathode. In the light emitting unit 10c, since the current injected from the p-side contact electrode 20c into the stacked body from the n-type semiconductor film 12 to the p-type semiconductor film 19 mainly flows downward (in the thickness direction of the stacked body), portions of the n-type semiconductor film 12, the third semiconductor film 17, and the p-type semiconductor film 19 located immediately below the p-side contact electrode 20c mainly function as the n-type semiconductor layer 12c, the light emitting layer 17c, and the p-type semiconductor layer 19c, respectively.

The sheet resistance of the p-type semiconductor film 19 is preferably 1000 Ω/□ (ohms per square) or more in order to prevent current diffusion in the in-plane direction. As a result, the direction in which the current injected from the p-side contact electrodes 20a, 20b, and 20c into the stacked body from the n-type semiconductor film 12 to the p-type semiconductor film 19 flows can be effectively directed downward.

As long as the p-type semiconductor film 19 has a thickness and conductivity which make ohmic contact with the p-side contact electrodes 20a to 20c, the sheet resistance of the p-type semiconductor film 19 can be set freely within a range which can prevent current diffusion in the in-plane direction. For example, values of 10000 Ω/□ or more and 100000 Ω/□ or more can be taken depending on the pitch of the light emitting units 10a to 10c.

As described above, the current injected from the p-side contact electrodes 20a, 20b, and 20c into the stacked body from the n-type semiconductor film 12 to the p-type semiconductor film 19 mainly flows downward. However, when the distance D1 in the plane direction of the p-side contact electrodes 20a, 20b, and 20c (the plane direction of the light emitting device 1, that is, the horizontal direction in FIG. 1) is small, there is a risk that the current injected from the p-side contact electrodes 20a, 20b, and 20c will flow into the adjacent light emitting unit.

For example, that the current injected from the p-side contact electrode 20c of the light emitting unit 10c flows into the adjacent light emitting unit 10b to cause the light emitting layer 15b of the light emitting unit 10b to emit light, that the current injected from the p-side contact electrode 20b of the light emitting unit 10b flows into the adjacent light emitting unit 10b to cause the light emitting layer 13a of the light emitting unit 10a to emit light, or the like may occur. In such a case, the color purity and contrast of light emitted from the light emitting units 10a to 10c may deteriorate.

Such a problem that the current for causing a particular light emitting unit 10 to emit light causes the light emitting layer of the adjacent light emitting unit 10 to emit light is caused by the n-type semiconductor layers 12a to 12c and p-type semiconductor layers 19a to 19c of the plurality of light emitting units 10a to 10c being provided in the n-type semiconductor film 12 and the p-type semiconductor film 19, which are single continuous films and used commonly in the plurality of light emitting units 10a to 10c. In order to form a circuit in which the plurality of light emitting units 10a to 10c are connected in parallel by the n-type semiconductor film 12 and the p-type semiconductor film 19, the current for causing a particular light emitting unit 10 out of the light emitting units 10a to 10c to emit light can cause the light emitting layer of the adjacent light emitting unit 10 to emit light.

In the light emitting device 1, the width of the p-side contact electrodes 20a to 20c is smaller than the width of the p-side junction electrodes 21a to 21c. Therefore, the distance from the end of the p-side contact electrodes 20a to 20c in the plane direction to the adjacent light emitting unit 10 becomes large, and the current for causing a particular light emitting unit 10 to emit light causes the light emitting layer of the adjacent light emitting unit 10 to emit light, which can reduce deterioration in the color purity and contrast of the light emitted from the light emitting units 10a to 10c.

The distance D1 between the contact electrodes 20a to 20c in the plane direction is set according to the light emitting area of each light emitting unit 10, that is, the pixel size of the display region composed of the plurality of light emitting units 10. For example, when the pixel size is about 1 the distance D1 is set to 1 μm or more, or 2 μm or more.

The n-type semiconductor film 12 is made of an n-type semiconductor containing donors. The p-type semiconductor film 19 is made of a p-type semiconductor containing acceptors.

The first semiconductor film 13, the first intermediate film 14, the second semiconductor film 15, the second intermediate film 16, the third semiconductor film 17, and the third intermediate film 18 are undoped (intentionally added dopants are not contained) or are made of an n-type semiconductor.

Typically, the n-type semiconductor film 12, the first semiconductor film 13, the first intermediate film 14, the second semiconductor film 15, the second intermediate film 16, the third semiconductor film 17, the third intermediate film 18, and the p-type semiconductor film 19 are made of a nitride semiconductor (III to V group semiconductor using nitrogen as a V group element).

For example, the n-type semiconductor film 12, the first intermediate film 14, the second intermediate film 16, the third intermediate film 18, and the p-type semiconductor film 19 are made of Al×InyGazN(x+y+z=1, z>0). The first semiconductor film 13, the second semiconductor film 15, and the third semiconductor film 17 have a multi quantum well structure with InvGawN(v+w=1) layers and GaN layers as wells and barriers, respectively. The In composition v of the second semiconductor film 15 is higher than the In composition v of the first semiconductor film 13, and the In composition v of the third semiconductor film 17 is higher than the In composition v of the second semiconductor film 15.

Typically, the light emission colors of the light emitting unit 10a, the light emitting unit 10b, and the light emitting unit 10c are blue, green, and red, respectively. In the present embodiment, the color of light with a wavelength of 430 to 480 nm is blue, the color of light with a wavelength of 500 to 550 nm is green, and the color of light with a wavelength of 600 to 680 nm is red.

The first semiconductor film 13 for emitting blue light in the light emitting layer 13a of the light emitting unit 10a has a multi quantum well structure with, for example, an InvGawN (v+w=1, 0.14≤v≤0.22) layer and a GaN layer as a well and a barrier, respectively. The second semiconductor film 15 for emitting green light in the light emitting layer 15b of the light emitting unit 10b has a multi quantum well structure with, for example, an InvGawN (v+w=1, 0.26≤v≤0.33) layer and a GaN layer as a well and a barrier, respectively. The third semiconductor film 17 for emitting red light in the light emitting layer 17c of the light emitting unit 10c has a multi quantum well structure with, for example, an InvGawN (v+w=1, 0.39≤v≤0.48) layer and a GaN layer as a well and a barrier, respectively.

The thickness of the n-type semiconductor film 12 in each light emitting unit is, for example, 1 to 5 μm. The thicknesses of the first semiconductor film 13, the second semiconductor film 15, and the third semiconductor film 17 are, for example, 6 to 100 nm. The thickness of the first intermediate film 14 and the second intermediate film 16 is, for example, 2 to 100 nm. The thickness of the third intermediate film 18 is, for example, 5 to 10 nm. The thickness of the p-type semiconductor film 19 is, for example, 10 to 200 nm. The contact electrodes 20a to 20c are made of, for example, ITO (Indium Tin Oxide) or IZO (Indium Zinc Oxide). The p-side junction electrodes 21a to 21c are made of, for example, a Ti/Au stacked body. The n-side junction electrode 22 is made of, for example, a Ti/Al stacked body. For example, the width W1 of the p-side contact electrodes 20a to 20c, the width W2 of the p-side junction electrodes 21a to 21c, and the distance D2 in the plane direction of the p-side junction electrodes 21a to 21c are 1 to 3 μm, 2 to 5 μm, and 2 to 5 μm, respectively.

(Mechanism of Light Emission)

The supposed mechanism of light emission of the light emitting unit 10c will be described below. In the light emitting unit 10c, by applying a voltage between the n-side junction electrode 22 and the p-side junction electrode 21c so that the side of the p-type semiconductor film 19 becomes an anode and the side of the n-type semiconductor film 12 becomes a cathode, electrons are injected from n-side junction electrode 22 and holes are injected from the p-side junction electrode 21c into the stacked body from the n-type semiconductor film 12 to the p-type semiconductor film 19.

Most of the holes injected from the p-side junction electrode 21c and entering the third semiconductor film 17 remain in the third semiconductor film 17. This is because the height of the barrier of the second intermediate film 16 viewed from the third semiconductor film 17 is high and it is difficult to cross this barrier.

On the other hand, electrons injected from the n-side junction electrode 22 and entering the first semiconductor film 13 can move to the third semiconductor film 17 relatively easily. This is because the height of the barrier of the first intermediate film 14 viewed from the first semiconductor film 13 and the height of the barrier of the second intermediate film 16 viewed from the second semiconductor film 15 are lower than the height of the barrier of the second intermediate film 16 as viewed from the third semiconductor film 17 and the mobility of electrons is higher than the mobility of holes.

For the above reasons, among the first semiconductor film 13, the second semiconductor film 15, and the third semiconductor film 17, electrons and holes recombine in the third semiconductor film 17, which is the closest to the p-side junction electrode 21c, and light emission occurs. That is, the light emitting layer 17c provided in the third semiconductor film 17 emits light.

In the light emitting unit 10b, for the same reason as in the light emitting unit 10c, out of the first semiconductor film 13 and the second semiconductor film 15, electrons and holes recombine in the second semiconductor film 15, which is closest to the p-side junction electrode 21b, and light emission occurs. That is, the light emitting layer 15b provided in the second semiconductor film 15 emits light.

The bandgap of the second intermediate film 16 is preferably smaller than the bandgap of the first intermediate film 14. This increases the efficiency of injecting electrons into the third semiconductor film 17. On the other hand, even if the bandgap of the second intermediate film 16 is smaller than the bandgap of the first intermediate film 14, if it is larger than the bandgap of the first semiconductor film 13, it is considered that the holes in the third semiconductor film 17 hardly cross the barrier of the second intermediate film 16 to move to the second semiconductor film 15.

(Method for Manufacturing Light Emitting Device)

An example of a method for manufacturing the light emitting device 1 will be described below.

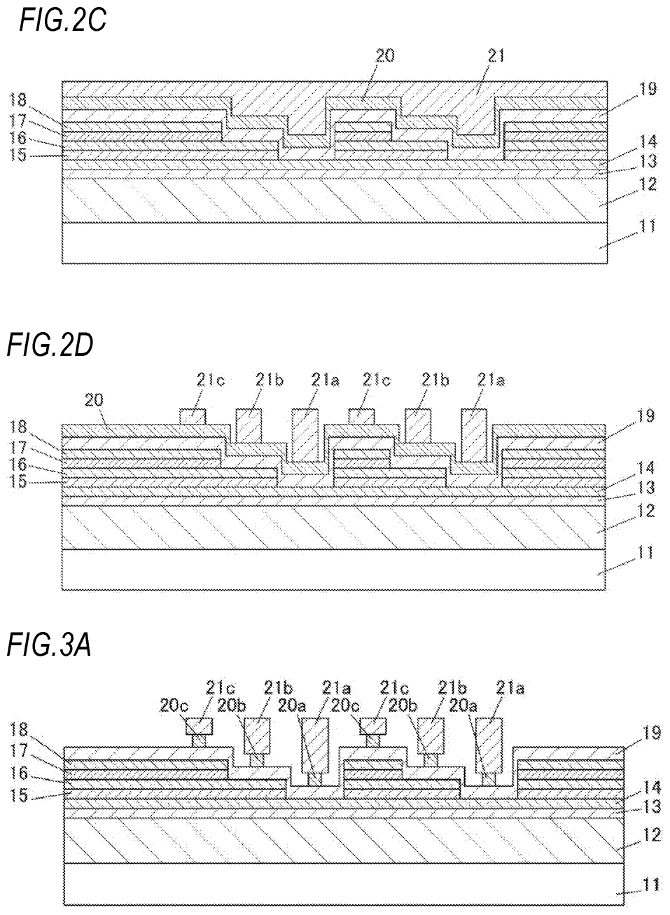

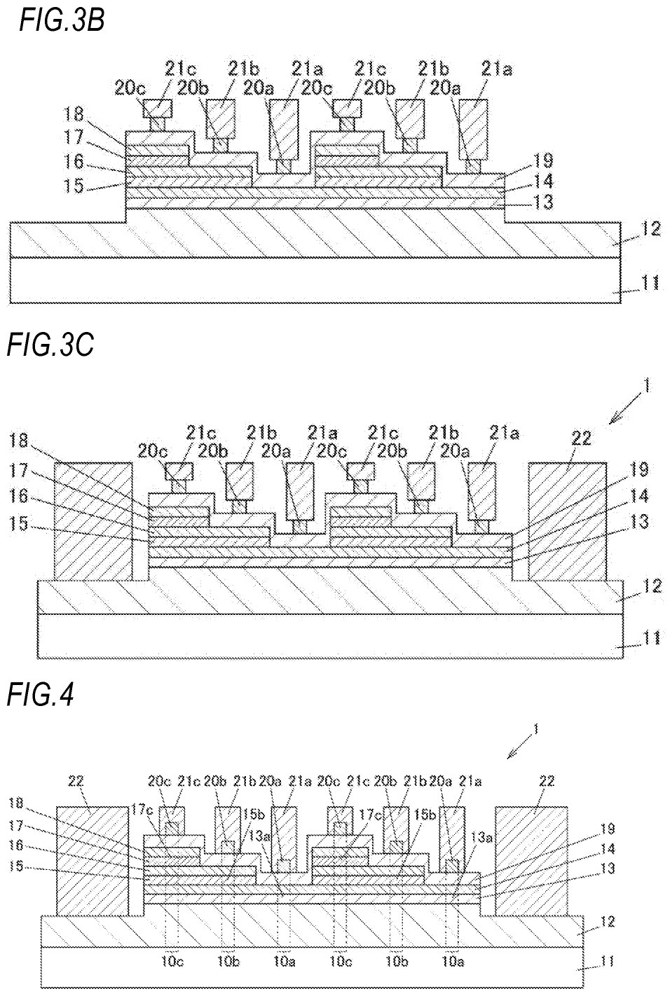

FIGS. 2A to 2D and 3A to 3C are vertical cross-sectional views illustrating manufacturing steps of the light emitting device 1 according to the first embodiment of the present disclosure.

First, as illustrated in FIG. 2A, the n-type semiconductor film 12, the first semiconductor film 13, the first intermediate film 14, the second semiconductor film 15, the second intermediate film 16, the third semiconductor film 17, and the third intermediate film 18 are stacked in this order on the substrate 11.

Next, as illustrated in FIG. 2B, after patterning the second semiconductor film 15, the second intermediate film 16, the third semiconductor film 17, and the third intermediate film 18, the p-type semiconductor film 19 is formed.

Patterning of the second semiconductor film 15, the second intermediate film 16, the third semiconductor film 17, and the third intermediate film 18 is performed by, for example, lithography and reactive ion etching (RIE). The first intermediate film 14 functions as an etching stopper when removing the second semiconductor film 15 in the region where the light emitting unit 10a is provided by etching, and prevents the first semiconductor film 13 from being scraped by over-etching. Also, the second intermediate film 16 functions as an etching stopper when removing the third semiconductor film 17 in the region where the light emitting unit 10b is provided by etching, and prevents the second semiconductor film 15 from being scraped by over-etching.

Next, as illustrated in FIG. 2C, on the p-type semiconductor film 19, a film 20 made of the material of the p-side contact electrodes 20a to 20c and a film 21 made of the material of the p-side junction electrodes 21a to 21c are formed.

Next, as illustrated in FIG. 2D, the film 21 is patterned to form p-side junction electrodes 21a to 21c. Patterning of the film 21 is performed by, for example, lithography and RIE. When lithography and dry etching such as RIE are used for patterning the film 21, a finer pattern can be formed than when lift-off or the like is used.

In the etching of the film 21, the film 20 made of ITO or the like functions as an etching stopper and prevents the p-type semiconductor film 19 from being scraped by over-etching. For example, in a case where the p-side junction electrodes 21a to 21c are made of Ti/Au and the p-side contact electrodes 20a to 20c are made of ITO or IZO, a CF4+O2 mixed gas is used as a dry etching gas for etching the film 21, and since ITO and IZO have sufficient resistance to the CF4+O2 mixed gas, the film 20 functions as an etching stopper.

Next, as illustrated in FIG. 3A, the film 20 is patterned to form p-side contact electrodes 20a to 20c. The patterning of the film 20 is performed by wet etching using the A-side junction electrodes 21a to 21c formed in the previous step as masks. Since the wet etching also progresses in the lateral direction, the width of the p-side contact electrodes 20a to 20c can be made smaller than the width of the p-side junction electrodes 21a to 21c, which are masks.

Next, as illustrated in FIG. 3B, in order to expose the region for connecting the n-side junction electrode 22 of the n-type semiconductor film 12, the first semiconductor film 13, the first intermediate film 14, the second semiconductor film 15, the second intermediate film 16, the third semiconductor film 17, and the third intermediate film 18, and a part of the p-type semiconductor film 19 are removed by lithography and RIE.

Next, as illustrated in FIG. 3C, the n-side junction electrode 22 is formed on the exposed region of the n-type semiconductor film 12 to obtain the light emitting device 1.

(Modification of Light Emitting Device)

FIG. 4 is a vertical cross-sectional view of a modification of the light emitting device 1 according to the first embodiment of the present disclosure. In the modification illustrated in FIG. 4, the p-side junction electrodes 21a to 21c cover the side surfaces of the p-side contact electrodes 20a to 20c. This structure is obtained by forming the p-side junction electrodes 21a to 21c after forming the p-side contact electrodes 20a to 20c.

Specifically, after going through the steps up to the step of forming the p-type semiconductor film 19 illustrated in FIG. 2B, the film 20 is formed and patterned to form A-side contact electrodes 20a to 20c, and then, the film 21 is formed and patterned to form the p-side junction electrodes 21a to 21c.

In this structure, although the p-side junction electrodes 21a to 21c are in contact with the p-type semiconductor film 19, since the contact resistance between the p-side junction electrodes 21a to 21c made of a Ti/Au stacked body or the like and the p-type semiconductor film 19 made of a nitride semiconductor or the like is much larger than the contact resistance between the p-side contact electrodes 20a to 20c made of ITO or the like and the p-type semiconductor film 19, current cannot flow directly from the p-side junction electrodes 21a to 21c to the p-type semiconductor film 19. Therefore, since the p-side junction electrodes 21a to 21c are in contact with the p-type semiconductor film 19, the current for causing a particular light emitting unit 10 to emit light does not easily flow into the adjacent light emitting unit 10.

(Mounting Example of Light Emitting Device)

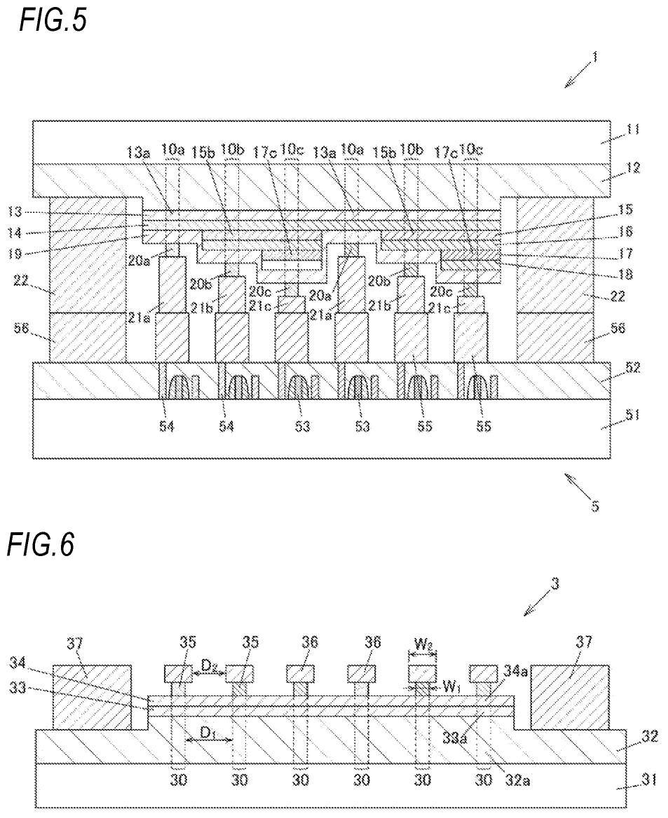

FIG. 5 is a vertical cross-sectional view of a mounting example of the light emitting device 1 according to the first embodiment of the present disclosure. In the example illustrated in FIG. 5, the light emitting device 1 is flip-chip mounted on a drive LSI5, which is the backplane. In this case, the drive LSI5 converts the power supply and signal input from the outside into a drive current signal and injects the drive current signal into the light emitting device 1.

In the drive LSI5, for example, a plurality of MOS transistors 53 are provided in an interlayer insulating film 52 on a substrate 51. On the interlayer insulating film 52, an electrode 55 connected to source/drain regions of the MOS transistors 53 via contact plugs 54 and an electrode 56 connected to the ground are provided. The p-side junction electrodes 21a to 21c and the n-side junction electrode 22 of the light emitting device 1 are connected to the electrodes 55 and 56 of the drive LSI5, respectively.

### Effect of First Embodiment

In the light emitting device 1 according to the first embodiment of the present disclosure, the width of the p-side contact electrodes 20a to 20c is smaller than the width of the p-side junction electrodes 21a to 21c. Therefore, the distance from the end of the p-side contact electrodes 20a to 20c in the plane direction to the adjacent light emitting unit 10 becomes large, and the current for causing a particular light emitting unit 10 to emit light causes the light emitting layer of the adjacent light emitting unit 10 to emit light, which can reduce deterioration in the color purity and contrast of the light emitted from the light emitting units 10a to 10c.

### Second Embodiment

The second embodiment of the present disclosure differs from the first embodiment in that the plurality of light emitting units provided in the light emitting device emit the same color. Descriptions of the same points as in the first embodiment will be omitted or simplified. FIG. 6 is a vertical cross-sectional view of a light emitting device 3 according to the second embodiment of the present disclosure. The light emitting device 3 includes a substrate 31 such as a sapphire substrate, and a plurality of light emitting units 30 provided side by side on the substrate 31 and independently emitting light in the same color. The number of light emitting units 30 provided in the light emitting device 3 is not particularly limited.

The light emitting device 3 includes an n-type semiconductor film 32, a semiconductor film 33 on the n-type semiconductor film 32, and a p-type semiconductor film 34 on the semiconductor film 33. The n-type semiconductor film 32, the semiconductor film 33, and the p-type semiconductor film 34 are each a single continuous film commonly used for the plurality of light emitting units 30. The n-type semiconductor film 32 is used as an n-type semiconductor layer 32a of the plurality of light emitting units 30. The semiconductor film 33 is used as a light emitting layer 33a of the plurality of light emitting units 30. The p-type semiconductor film 34 is used as a p-type semiconductor layer 34a of the plurality of light emitting units 30.

Each of the light emitting units 30 includes an n-type semiconductor layer 32a which is part of the n-type semiconductor film 32, a light emitting layer 33a which is part of the semiconductor film 33 on the n-type semiconductor layer 32a, a p-type semiconductor layer 34a which is part of the p-type semiconductor film 34 on the light emitting layer 33a, a p-side contact electrode 35 connected to the upper surface of the p-type semiconductor layer 34a, and a p-side junction electrode 36 connected to the upper surface of the p-side contact electrode 35.

An n-side junction electrode 37 is connected on the n-type semiconductor film 32 commonly used for the plurality of light emitting units 30. In the light emitting device 3, since the plurality of light emitting units 30 normally constitute one display region, the n-side junction electrode 37 is preferably provided outside the plurality of light emitting units 30.

In the light emitting unit 30, the light emitting layer 33a emits light when a voltage is applied between the n-side junction electrode 37 and p-side junction electrode 36 so that the side of the p-type semiconductor film 34 is the anode and the side of the n-type semiconductor film 32 is the cathode. In the light emitting unit 30, since the current injected from the p-side contact electrode 35 into the stacked body from the n-type semiconductor film 32 to the p-type semiconductor film 34 mainly flows downward (in the thickness direction of the stacked body), the portions of the n-type semiconductor film 32, the semiconductor film 33, and the p-type semiconductor film 34 located immediately below the p-side contact electrode 35 mainly function as the n-type semiconductor layer 32a, the light emitting layer 33a, and the p-type semiconductor layer 34a, respectively.

The sheet resistance of the p-type semiconductor film 34 is preferably 1000 Ω/□ or more in order to prevent current diffusion in the in-plane direction. As a result, the direction in which the current injected from the p-side contact electrode 35 into the stacked body from the n-type semiconductor film 32 to the p-type semiconductor film 34 flows can be effectively directed downward.

As long as the p-type semiconductor film 34 has a thickness and conductivity which make ohmic contact with the p-side contact electrode 35, the sheet resistance of the p-type semiconductor film 34 can be set freely within a range which can prevent current diffusion in the in-plane direction. For example, values of 10000 Ω/□ or more and 100000 Ω/□ or more can be taken depending on the pitch of the light emitting unit 30.

As described above, the current injected from the p-side contact electrode 35 into the stacked body from the n-type semiconductor film 32 to the p-type semiconductor film 34 mainly flows downward. However, when the distance D1 in the plane direction of the p-side contact electrode 35 (the plane direction of the light emitting device 3, that is, the horizontal direction in FIG. 6) is small, there is a risk that the current injected from the p-side contact electrode 35 flows into the adjacent light emitting unit.

For example, current injected from the p-side contact electrode 35 of a particular light emitting unit 30 may flow into the adjacent light emitting unit 30 and cause the light emitting layer 33a to emit light. In such a case, the contrast of light emitted from the plurality of light emitting units 30 may deteriorate.

The problem that the current for causing a particular light emitting unit 30 to emit light causes the light emitting layer 33a of the adjacent light emitting unit 30 to emit light can occur because the n-type semiconductor film 32a and the p-type semiconductor film 34a included in the plurality of light emitting units 30 are included in the n-type semiconductor film 32 and the p-type semiconductor film 34, respectively, which are single continuous films commonly used for the plurality of light emitting units 30, so that a circuit in which the plurality of light emitting units 30 are connected in parallel by the n-type semiconductor film 32 and the p-type semiconductor film 34 is formed.

In the light emitting device 3, the width of the p-side contact electrode 35 is smaller than the width of the p-side junction electrodes 36. Therefore, the distance from the end of the p-side contact electrode 35 in the plane direction to the adjacent light emitting unit 30 becomes large, and the current for causing a particular light emitting unit 30 to emit light causes the light emitting layer of the adjacent light emitting unit 30 to emit light, which can reduce deterioration in the contrast of the light emitted from the plurality of light emitting units 30.

The distance D1 between the p-side contact electrodes 35 in the plane direction is set according to the light emitting area of each light emitting unit 30, that is, the pixel size of the display region composed of the plurality of light emitting units 30. For example, if the pixel size is about 1 μm, the distance D1 is set to 1 μm or more, or 2 μm or more.

The substrate 31, the n-type semiconductor film 32, the p-type semiconductor film 34, the p-side contact electrode 35, the p-side junction electrode 36, and the n-side junction electrode 37 are made of the same material and have the same thickness as the substrate 11, the n-type semiconductor film 12, the p-type semiconductor film 19, the p-side contact electrodes 20a to 20c, the p-side junction electrodes 21a to 21c, and the n-side junction electrode 22 of the light emitting device 1 according to the first embodiment. The semiconductor film 33 is made of the same material and has the same thickness as the first semiconductor film 13, the second semiconductor film 15, and the third semiconductor film 17 of the light emitting device 1. For example, the width W1 of the p-side contact electrode 35, the width W2 of the p-side junction electrode 36, and the distance D2 in the plane direction of the p-side junction electrode 36 are 1 to 3 μm, 2 to 5 μm, and 2 to 5 μm, respectively.

As in the modification of the light emitting device 1 illustrated in FIG. 4, the p-side junction electrode 36 may cover the side surface of the p-side contact electrode 35.

Like the light emitting device 1, the light emitting device 3 can be flip-chip mounted on, for example, the drive LSI5 or the like.

### Effect of Second Embodiment

In the light emitting device 3 according to the second embodiment of the present disclosure, the width of the p-side contact electrode 35 is smaller than the width of the p-side junction electrode 36. Therefore, the distance from the end of the p-side contact electrode 35 in the plane direction to the adjacent light emitting unit 30 becomes large, and the current for causing a particular light emitting unit 30 to emit light causes the light emitting layer of the adjacent light emitting unit 30 to emit light, which can reduce deterioration in the contrast of the light emitted from the plurality of light emitting units 30.

Although the embodiments of the present invention have been described above, the present invention is not limited to the above embodiments, and various modifications can be made without departing from the gist of the invention. Also, the elements of the above-described embodiments can be freely combined without departing from the gist of the invention.

Moreover, the embodiments described above do not limit the invention according to the claims. Also, it should be noted that not all combinations of features described in the embodiments are essential to the means for solving the problems of the invention.

What is claimed is:

1. A light emitting device comprising:
a plurality of light emitting units located side by side on a single substrate and each emitting light independently, wherein:
each of the plurality of light emitting units includes:
an n-type semiconductor layer;
a light emitting layer above the n-type semiconductor layer;
a p-type semiconductor layer above the light emitting layer;
a p-side contact electrode connected to an upper surface of the p-type semiconductor layer; and
a p-side junction electrode connected to an upper surface of the p-side contact electrode;
the n-type semiconductor layer and the p-type semiconductor layer of the plurality of light emitting units are respectively provided in an n-type semiconductor film and a p-type semiconductor film, which are single continuous films commonly used for the plurality of light emitting units;
an n-side junction electrode is commonly connected to the n-type semiconductor layers of the plurality of light emitting units; and
the width of the p-side contact electrode is smaller than the width of the p-side junction electrode.

2. The light emitting device according to claim 1, wherein
the p-side junction electrode does not cover a side surface of the p-side contact electrode.

3. The light emitting device according to claim 1, wherein
the p-side junction electrode covers a side surface of the p-side contact electrode.

4. The light emitting device according to claim 1, wherein
in the plurality of light emitting units, adjacent light emitting units emit light in different colors.

5. The light emitting device according to claim 1, wherein
the n-side junction electrode is located outside the plurality of light emitting units.
